(19) United States
(12) Patent Application Publication
(10) Pub. No.: US 2026/0324310 A1
(43) Pub. Date: Oct. 15, 2026

(54) FILM-FORMING METHOD AND FILM-FORMING APPARATUS

(71) Applicant: Tokyo Electron Limited, Tokyo (JP)

(72) Inventors: Tomohiro NAKAGAWA, Gyeonggi-do (KR); Takashi FUSE, Tokyo (JP); Yumiko KAWANO, Yamanashi (JP); Shuji AZUMO, Yamanashi (JP)

(21) Appl. No.: 19/689,300

(22) Filed: May 27, 2026

Related U.S. Application Data
(63) Continuation of application No. PCT/JP2024/040785, filed on Nov. 18, 2024.

(30) Foreign Application Priority Data
Nov. 30, 2023 (JP) 2023-202355

(51) Int. Cl. H10P 14/60; H01J 37/32; H10W 20/00

(52) U.S. Cl. CPC H10P 14/6336; H01J 37/32449; H10P 14/6506; H10W 20/074; H01J 2237/3321

(57) ABSTRACT

A film-forming method includes: preparing a substrate, the substrate including, on a surface of the substrate, a first region in which an insulating film is exposed and a second region in which a conductive film is exposed; forming a catalyst layer selectively in a specific region of the first region rather than in the second region, the catalyst layer being for promoting formation of a target film containing silicon (Si) and oxygen (O), and the specific region being spaced apart from a boundary between the first region and the second region; and supplying, after the formation of the catalyst layer, a precursor gas to the surface of the substrate, thereby growing the target film from the specific region toward the boundary, the precursor gas containing a silanol group (SiOH group).

### CROSS-REFERENCE TO RELATED APPLICATIONS

This application is a continuation application of International Application No. PCT/JP2024/040785, filed on Nov. 18, 2024, and designated the U.S., which is based upon and claims priority to Japanese Patent Application No. 2023-202355, filed on Nov. 30, 2023, the entire contents of which are incorporated herein by reference.

### TECHNICAL FIELD

The present disclosure relates to a film-forming method and a film-forming apparatus.

### BACKGROUND

A film-forming method described in Japanese National Publication of International Publication No. 2005-521792 includes exposing a heated substrate to silanol vapor to form a silica layer on a specific region of the substrate. The specific region on which the silica layer is formed is a region containing a metal or metalloid compound having Lewis acid properties.

A film-forming method described in U.S. Patent Application Publication No. 2021/301392 includes, in the following order: forming a polyimide film or a self-assembled monolayer selectively on a surface of a metal film with respect to a surface of a dielectric film; and forming a silicon oxide film selectively on the surface of the dielectric film with respect to the surface of the metal film. The silicon oxide film is formed using a metal catalyst and silanol.

A film-forming method described in Japanese Patent Application Laid-Open Publication No. 2019-096881 includes: forming a metal-containing catalyst layer on a surface of a metal oxide layer covering a surface of a metal film and on a surface of a dielectric film; removing the metal-containing catalyst layer on the metal oxide layer by removing the metal oxide layer; and forming an SiO₂ film on the metal-containing catalyst layer remaining on the surface of the dielectric film.

A film-forming method described in Japanese Patent Application Laid-Open Publication No. 2022-159050 includes: supplying a metal-containing catalyst gas to a surface of a substrate; supplying hydrogen radicals to the surface of the substrate; and supplying a silicon precursor gas containing silanol to the surface of the substrate.

A film-forming method described in Japanese Patent Application Laid-Open Publication No. 2020-056104 includes, in the following order: forming a passivation film selectively on a surface of a metal film with respect to a surface of a dielectric film; and forming a target film selectively on the surface of the dielectric film with respect to the surface of the metal film. The target film is an oxide film or a nitride film.

A film-forming method described in Japanese Patent Application Laid-Open Publication No. 2020-147829 includes forming an Ru film selectively on a surface of a conductive film with respect to a surface of an insulating film. The Ru film is formed by alternately supplying Ru(EtCp)₂ gas and O₂ gas to the surface of a substrate. The surface of the insulating film has OH groups, and the OH groups inhibit adsorption of the Ru(EtCp)₂ gas, so that the Ru film is selectively formed on the surface of the conductive film.

### SUMMARY

An aspect of a film-forming method according to the present disclosure includes: preparing a substrate, the substrate including, on a surface of the substrate, a first region in which an insulating film is exposed and a second region in which a conductive film is exposed; forming a catalyst layer selectively in a specific region of the first region rather than in the second region, the catalyst layer being for promoting formation of a target film containing silicon (Si) and oxygen (O), and the specific region being spaced apart from a boundary between the first region and the second region; and supplying, after the formation of the catalyst layer, a precursor gas to the surface of the substrate, thereby growing the target film from the specific region toward the boundary, the precursor gas containing a silanol group (SiOH group).

### BRIEF DESCRIPTION OF THE DRAWINGS

FIG. 1 is a flowchart illustrating a film-forming method according to an embodiment;

FIG. 2 is a cross-sectional view illustrating S101 to S104 according to an embodiment;

FIG. 3 is a cross-sectional view illustrating S101 to S104 according to a first modification;

FIG. 4 is a cross-sectional view illustrating S101 to S104 according to a second modification;

FIG. 5 is a flowchart illustrating a first example of S102 in FIG. 1;

FIG. 6 is a cross-sectional view illustrating the first example of S102 in FIG. 1;

FIG. 7 is a cross-sectional view illustrating a first example of S102a in FIGS. 5 and 6;

FIG. 8 is a cross-sectional view illustrating a second example of S102a in FIGS. 5 and 6;

FIG. 9 is a flowchart illustrating a second example of S102 in FIG. 1;

FIG. 10 is a cross-sectional view illustrating the second example of S102 in FIG. 1;

FIG. 11 is a plan view illustrating a film-forming apparatus according to an embodiment; and

FIG. 12 is a cross-sectional view illustrating an example of a first processing unit illustrated in FIG. 11.

### DETAILED DESCRIPTION

An aspect of the present disclosure provides a technique of forming a target film containing silicon (Si) and oxygen (O) in a desired region.

Hereinafter, embodiments of the present disclosure will be described with reference to the drawings. Throughout the drawings, the same or corresponding components are denoted by the same reference signs, and repeated description thereof may be omitted.

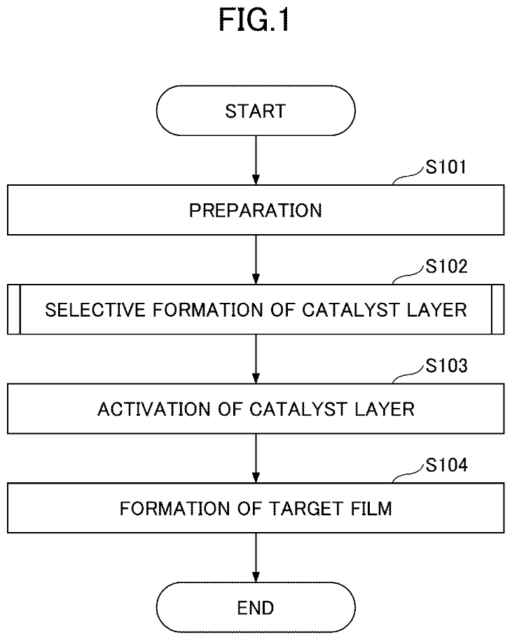

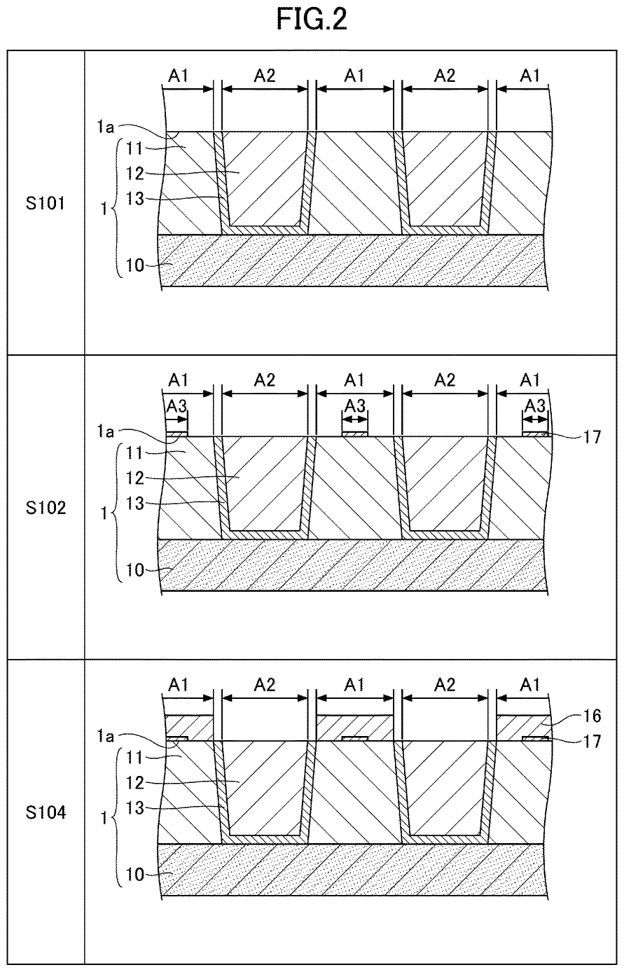

A film-forming method according to an embodiment will be described mainly with reference to FIGS. 1 and 2. The film-forming method includes, for example, Steps S101 to S104 illustrated in FIG. 1. However, the film-forming method does not necessarily include all of Steps S101 to S104 illustrated in FIG. 1, and may omit, for example, Step S103. In addition, the film-forming method may include a step other than Steps S101 to S104 illustrated in FIG. 1.

As illustrated in FIG. 2, Step S101 includes preparing a substrate 1. The substrate 1 includes a base substrate 10. The base substrate 10 is, for example, a silicon wafer, a compound semiconductor wafer, or a glass substrate. The substrate 1 includes, on a substrate surface 1a, a first region A1 in which an insulating film 11 is exposed and a second region A2 in which a conductive film 12 is exposed. The substrate surface 1a is, for example, an upper surface of the substrate 1. The insulating film 11 and the conductive film 12 are formed over the base substrate 10. A functional film (not illustrated) may be formed between the base substrate 10 and the insulating film 11 or between the base substrate 10 and the conductive film 12.

The insulating film 11 is, for example, an interlayer insulating film. The interlayer insulating film is preferably a low dielectric constant (low-k) film. The insulating film 11 is not particularly limited, and is, for example, an SiO film, an SiN film, an SiOC film, an SiON film, or an SiOCN film. Here, the term “SiO film” refers to a film containing silicon (Si) and oxygen (O). The atomic ratio of silicon (Si) to oxygen (O) in the SiO film is typically 1:2, but is not limited to 1:2. Similarly, each of the SiN film, the SiOC film, the SiON film, and the SiOCN film refers to a film containing the elements thereof, and is not limited to a stoichiometric ratio. The insulating film 11 has recesses on the substrate surface 1a. Each recess is a trench, a contact hole, or a via hole.

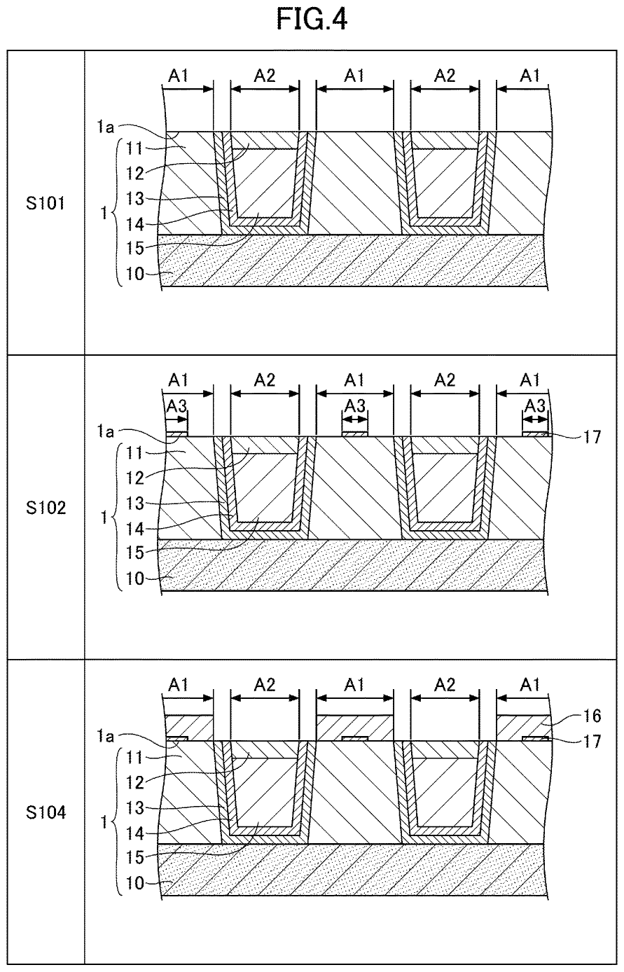

The conductive film 12 is, for example, filled in the recesses of the insulating film 11. The conductive film 12 is, for example, a metal film. The metal film is, for example, a Cu film, a Co film, an Ru film, a W film, or a Mo film. Note that the conductive film 12 may be a cap film. That is, as illustrated in FIG. 4, a second conductive film 15 may be embedded in the recesses of the insulating film 11, and the conductive film 12 may cover the second conductive film 15. The second conductive film 15 is formed of a metal different from that of the conductive film 12. For example, the second conductive film 15 is a Cu film, and the conductive film 12 (cap film) is a Co film or an Ru film. Moreover, the surface of the conductive film 12 and the surface of the insulating film 11 do not have to be flush with each other, and may have a step.

The substrate surface 1a may include, at a boundary between the first region A1 and the second region A2, a region in which a barrier film 13 is exposed. The barrier film 13 is formed between the insulating film 11 and the conductive film 12, and suppresses metal diffusion from the conductive film 12 into the insulating film 11. The barrier film 13 is not particularly limited, and is, for example, a TaN film or a TiN film. Here, the term “TiN film” refers to a film containing titanium (Ti) and nitrogen (N). The atomic ratio of Ti to N in the TiN film is typically 1:1, but is not limited to 1:1. Similarly, the TaN film refers to a film containing the elements thereof, and is not limited to a stoichiometric ratio.

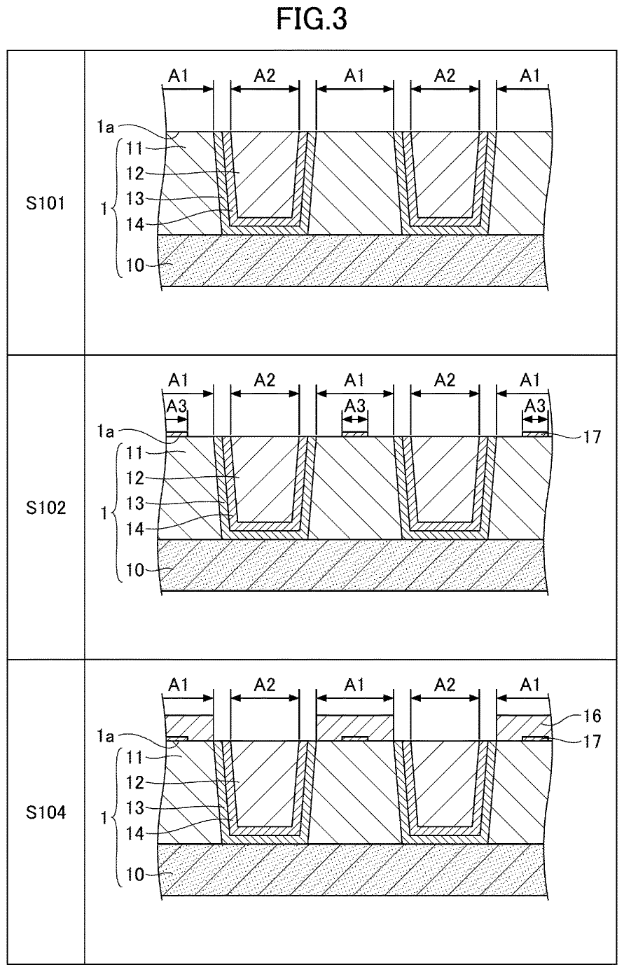

As illustrated in FIGS. 3 and 4, the substrate surface 1a may include, at a boundary between the first region A1 and the second region A2, a region in which a liner film 14 is exposed. The liner film 14 is formed between the conductive film 12 and the barrier film 13. The liner film 14 is formed on the barrier film 13 and assists formation of the conductive film 12. The conductive film 12 is formed on the liner film 14. For example, the conductive film 12 is a Cu film, and the liner film 14 is a Co film or an Ru film.

As illustrated in FIG. 2, Step S102 includes forming a catalyst layer 17 selectively in a specific region A3 of the first region A1 rather than in the second region A2. The specific region A3 of the first region A1 is a region spaced apart from the boundary between the first region A1 and the second region A2. A catalyst layer 17, as will be described in detail later, can be, for example, formed over the entire substrate surface 1a and then removed from regions other than the specific region A3, so as to remain only in the specific region A3.

The catalyst layer 17 is formed, for example, using a metal-catalyst-containing gas. The metal-catalyst-containing gas contains a metal catalyst. The metal-catalyst-containing gas is preferably an organometallic compound gas. Specific examples include an organoaluminum compound gas and an organotitanium compound gas. The organoaluminum compound gas is, for example, a trimethylaluminum (TMA) gas, a triethylaluminum (TEA) gas, a dimethylaluminum chloride gas, or a dimethylaluminum isopropoxide (DMAI) gas. The organotitanium compound gas is, for example, a tetrakis(dimethylamino)titanium (TDMAT) gas.

In the present embodiment, the catalyst layer 17 is formed using only a metal-catalyst-containing gas and contains only a metal catalyst. However, the metal catalyst may be oxidized with an oxidizing gas, and the catalyst layer 17 may contain oxygen (O) in addition to the metal catalyst. That is, the catalyst layer 17 may be a metal oxide layer. By oxidizing the metal catalyst, desorption or diffusion of the metal catalyst can be suppressed. The oxidizing gas is, for example, an H₂O gas, an O₂ gas, or an O₃ gas.

Step S103 includes activating the catalyst layer 17 by supplying a gas in a plasma state to the substrate surface 1a on which the catalyst layer 17 has been formed. A gas to be formed into a plasma is hydrogen gas in the present embodiment, but is not limited to hydrogen gas, and may be a noble gas or a mixed gas of hydrogen gas and a noble gas. The noble gas is, for example, Ar gas or He gas. A gas to be formed into a plasma in Step S103 preferably does not include an oxygen-based gas in order to suppress oxidation of the conductive film 12. Activation of the catalyst layer 17 is particularly effective when the catalyst layer 17 is a metal oxide layer.

An example of processing conditions in Step S103 is shown below.
Flow rate of H₂ gas: 200 sccm to 3000 sccm
Flow rate of Ar gas: 0 sccm to 6000 sccm
Proportion of H₂ gas in a mixed gas of H₂ gas and Ar gas: 0 vol % to 100 vol %
Power supply frequency for plasma generation: 10 MHz to 60 MHz
Power for plasma generation: 50 W to 600 W
Processing time: 2 sec to 120 sec
Processing temperature: 80° C. to 350° C.
Processing pressure: 50 Pa to 1200 Pa

As illustrated in FIG. 2, Step S104 includes supplying a precursor gas to the substrate surface 1a to grow a target film 16 from the specific region A3 toward a boundary between the first region A1 and the second region A2. The precursor gas contains silanol groups (SiOH groups). The catalyst layer 17 promotes formation of the target film 16 by promoting a dehydration condensation reaction of the silanol groups. The target film 16 is preferably formed over the entire first region A1. However, the target film 16 preferably does not extend into the second region A2.

The silanol-group-containing gas used as the precursor gas is not particularly limited, and examples thereof include tris(tert-pentoxy)silanol (TPSOL), triethylsilanol, methyl bis(tert-pentoxy)silanol, and tris(tert-butoxy)silanol (TBSOL).

An example of processing conditions in Step S104 is shown below.
Flow rate of TPSOL gas: 0.1 g/min to 0.5 g/min
Processing time: 3 seconds to 300 seconds
Processing temperature: 80° C. to 350° C.
Processing pressure: 133 Pa to 1200 Pa

According to the present embodiment, before Step S104, the catalyst layer 17 for promoting growth of the target film 16 is formed only in the specific region A3 of the first region A1. Thus, even if the target film 16 grows from the specific region A3 toward the second region A2 in Step S104, extension of the target film 16 into the second region A2 can be suppressed. Therefore, the target film 16 can be formed selectively in a desired region (e.g., the first region A1). When the target film 16 has insulating properties, narrowing of an opening width of the insulating target film 16 can be suppressed, and an increase in resistance of a via interconnection in the second region A2 can be suppressed.

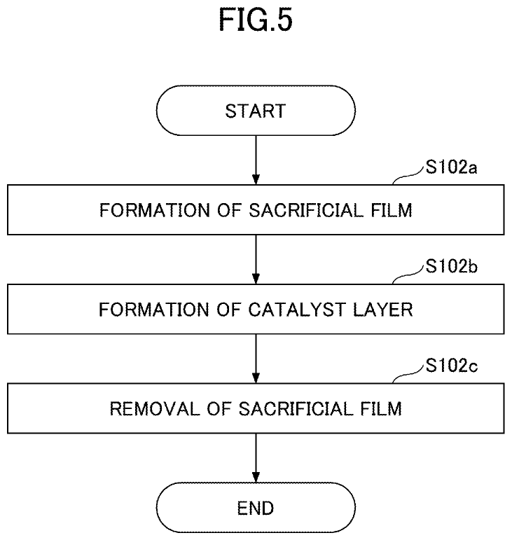

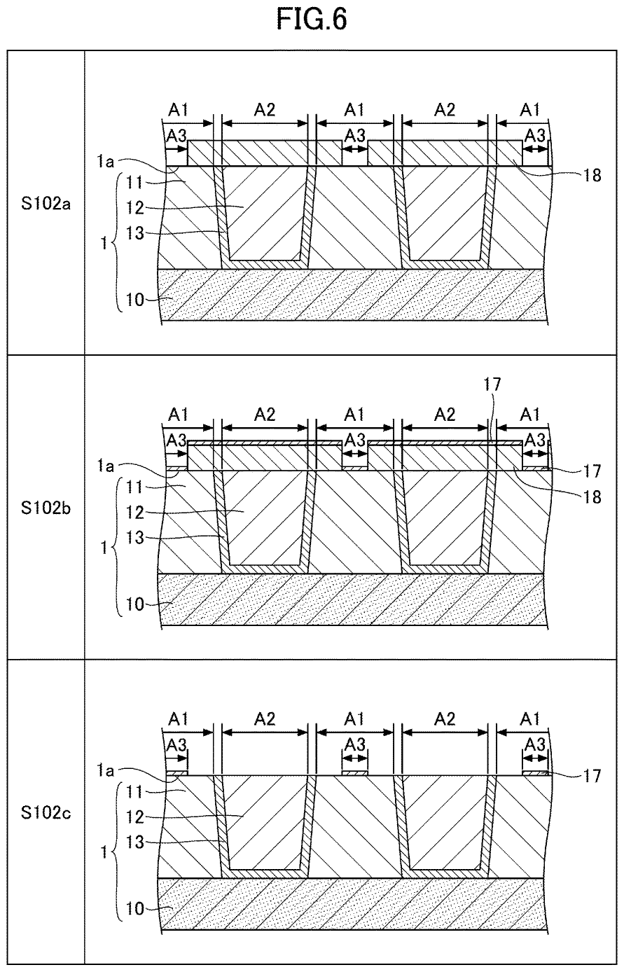

Next, a first example of Step S102 illustrated in FIG. 1 will be described with reference to FIGS. 5 and 6. Step S102 includes, for example, Steps S102a to S102c illustrated in FIGS. 5 and 6. However, Step S102 does not necessarily include all of Steps S102a to S102c illustrated in FIGS. 5 and 6. In addition, Step S102 may include a step other than Steps S102a to S102c illustrated in FIGS. 5 and 6.

As illustrated in FIG. 6, Step S102a includes forming a sacrificial film 18 at least in the entirety of the second region A2 and the first region excluding the specific region A3. As will be described in detail later, the sacrificial film 18 is formed selectively in the second region A2 rather than in the first region A1. However, the selectivity is not absolute, and the sacrificial film 18 is formed so as to extend from the second region A2 into the first region A1. Preferably, the sacrificial film 18 is formed over the entire substrate surface 1a except for the specific region A3.

As illustrated in FIG. 6, Step S102b includes forming the catalyst layer 17 on the first region A1 and the second region A2. In the present embodiment, the catalyst layer 17 is formed using only a metal-catalyst-containing gas and contains only a metal catalyst. However, the metal catalyst may be oxidized with an oxidizing gas, and the catalyst layer 17 may contain oxygen (O) in addition to the metal catalyst. That is, the catalyst layer 17 may be a metal oxide layer. Preferably, the catalyst layer 17 is formed over the entire substrate surface 1a.

As will be described in detail later, the sacrificial film 18 may be an inhibiting film that inhibits formation of the catalyst layer 17. Accordingly, the density of the catalyst layer 17 may differ between the specific region A3 in which no inhibiting film is formed and regions other than the specific region A3 in which the inhibiting film is formed. The catalyst layer 17 may be densely formed in the specific region A3 and sparsely formed in regions other than the specific region A3. Since it is sufficient that the catalyst layer 17 remains only in the specific region A3 upon completion of Step S102, the catalyst layer 17 may be sparsely formed in regions other than the specific region A3.

As illustrated in FIG. 6, Step S102c includes removing the sacrificial film 18 and leaving the catalyst layer 17 selectively in the specific region A3. By removing the sacrificial film 18, the catalyst layer 17 deposited on the sacrificial film 18 can be removed. A method for removing the sacrificial film 18 is selected as appropriate depending on the type of the sacrificial film 18. For example, when the sacrificial film 18 is a self-assembled monolayer, the self-assembled monolayer is decomposed and removed by supplying a gas in a plasma state to the substrate surface 1a. When the sacrificial film 18 is a metal film, the metal film is modified into a volatile substance and removed by supplying ClF₃ gas or O₃ gas to the substrate surface 1a.

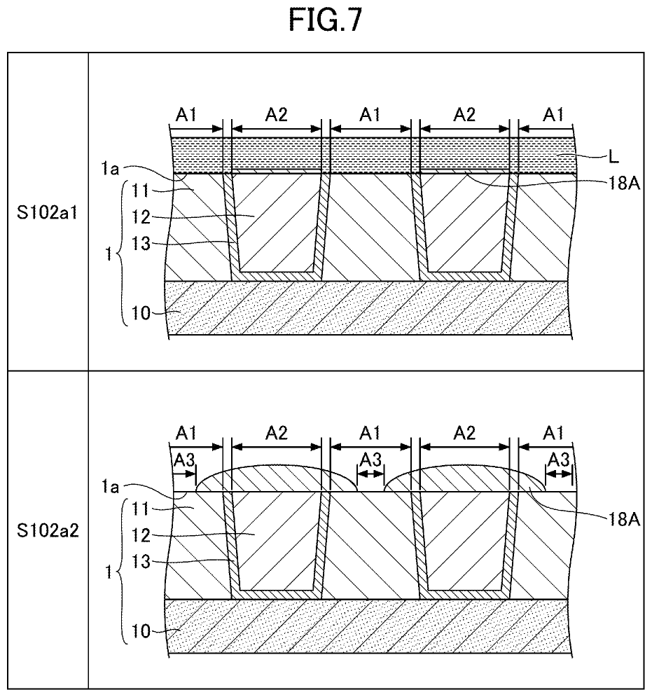

Next, a first example of Step S102a illustrated in FIGS. 5 and 6 will be described with reference to FIG. 7. In the first example of Step S102a, the sacrificial film 18 is a self-assembled monolayer 18A. Hereinafter, the self-assembled monolayer (SAM) 18A may be referred to as SAM 18A. As illustrated in FIG. 7, the first example of Step S102a includes applying a liquid L, which is an organic compound serving as a precursor of the SAM 18A, onto the substrate surface 1a (Step S102a1), and drying the applied liquid L (Step S102a2).

The organic compound is not particularly limited, and may include, for example, a thiol compound. Specific examples of the thiol compound include CF₃(CF₂)₅CH₂CH₂SH (1H,1H,2H,2H-perfluorooctanethiol: PFOT), CH₃(CH₂)₅SH (hexanethiol: HT), and CH₃(CH₂)₁₇SH (octadecanethiol). The thiol compound is more likely to be chemisorbed onto the surface of the conductive film 12 than onto the surface of the insulating film 11. Thus, the SAM 18A is formed selectively in the second region A2 rather than in the first region A1. However, the selectivity is not absolute, and the SAM 18A is formed so as to extend from the second region A2 into the first region A1.

The organic compound is not limited to a thiol compound. The organic compound may include a phosphonic acid compound, a carboxylic acid compound, or a nitro compound. Note that the organic compound may also include an olefin compound or an organosilane compound. The olefin compound is represented by the general formula “R—CH═CH₂.” The organosilane compound includes, for example, a trichlorosilane-based compound, a methoxysilane-based compound, or an ethoxysilane-based compound. The trichlorosilane-based compound is represented by the general formula “R—SiCl₃.” The methoxysilane-based compound is represented by the general formula “R—Si(OCH₃)₃.” The ethoxysilane-based compound is represented by the general formula “R—Si(OCH₂CH₃)₃.”

As described above, the organic compound is applied in the form of the liquid L. The liquid L is applied over the entire substrate surface 1a. In the present embodiment, the liquid L is applied by spin coating. However, the application method is not particularly limited, and dip coating, die coating, or the like may also be used. The organic compound is used in a state dissolved in an organic solvent. The organic solvent is, for example, IPA (isopropyl alcohol). The concentration of the organic compound in the liquid L, for example, ranges from 0.1 vol % to 10 vol %, inclusive. The liquid L can supply a larger amount of the organic compound to the substrate surface 1a than a gas. Therefore, the SAM 18 tends to extend from the second region A2 into the first region A1.

Drying of the liquid L includes heating the substrate 1. The heating temperature of the substrate 1 is preferably increased stepwise. The heating temperature of the substrate 1 preferably includes a temperature equal to or higher than the boiling point of the organic solvent. When the substrate 1 is heated, the organic solvent vaporizes. In the process, the liquid L accumulates selectively in the second region A2 rather than in the first region A1. The liquid L forms a convex surface due to surface tension. The liquid L has a height and spread corresponding to the surface tension, and extends from the second region A2. Accordingly, the SAM 18A is formed so as to extend from the second region A2 into the first region A1.

Step S102a may include cleaning the substrate surface 1a with a chemical solution or pure water before applying the liquid L. As a result, foreign matter can be removed. Step S102a may also include, after drying the applied liquid L, supplying an organic solvent to the substrate surface 1a to dissolve and remove unreacted organic compounds from the substrate surface 1a. Since the SAM 18A reacts with and is chemically adsorbed on the substrate surface 1a, the SAM 18A is less likely to dissolve in the organic solvent and remains on the substrate surface 1a.

Specific examples of Steps S102a1 and S102a2 are as follows. First, while the substrate 1 is vacuum-chucked on a spin chuck and rotated, a thiol-compound-containing solution, in which IPA or the like is used as a solvent, is dropped onto the center of the substrate surface 1a. The rotation of the substrate 1 is continued at the same rotational speed as, or at a higher rotational speed than, that at the time of dropping, to spin off the unreacted thiol-compound-containing solution from the substrate surface 1a and vaporize IPA serving as a solvent in regions of the substrate surface 1a where the thiol compound has reacted. Next, the substrate 1 is heated to further promote vaporization of IPA. Then, while the substrate 1 is again vacuum-chucked on the spin chuck and rotated, an organic solvent such as IPA is dropped onto the center of the substrate surface 1a to further promote removal of unreacted organic compounds. Thereafter, the substrate 1 is heated again to vaporize and remove the organic solvent such as IPA, and to enhance bonding between the substrate surface 1a and the thiol compound, thereby improving the insulating properties of the SAM 18A.

An example of processing conditions in Steps S102a1 and S102a2 is shown below.
Rotational speed during solution dropping: 100 rpm to 3000 rpm
Solution dropping time: 3 seconds to 120 seconds
Substrate heating temperature: 80° C. to 350° C.
Substrate heating time: 30 seconds to 1800 seconds

When the sacrificial film 18 is the SAM 18A, the SAM 18A functions as an inhibiting film that inhibits formation of the catalyst layer 17 in Step S102b. Accordingly, in Step S102b, the catalyst layer 17 is densely formed in the specific region A3 and sparsely formed in regions other than the specific region A3. In the present embodiment, the catalyst layer 17 is sparsely formed in regions other than the specific region A3. However, the catalyst layer 17 does not need to be formed at all.

When the sacrificial film 18 is the SAM 18A, Step S102c decomposes and removes the SAM 18A by supplying a gas in a plasma state to the substrate surface 1a. A gas to be formed into a plasma may be the same as the gas used in step S103. Thus, Step S102c can also serve as Step S103 (activation of the catalyst layer 17).

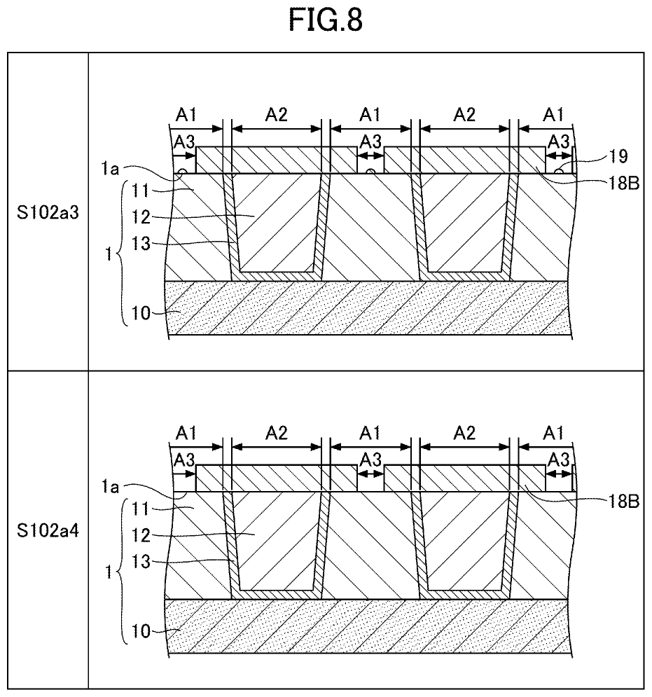

Next, a second example of Step S102a illustrated in FIGS. 5 and 6 will be described with reference to FIG. 8. In the second example of Step S102a, the sacrificial film 18 is a metal film 18B. The metal film 18B is advantageous in that, even if the metal film 18B remains in the second region A2 without being completely removed in Step S102c, the metal film 18B does not reduce the resistance of a via.

As illustrated in FIG. 8, the second example of Step S102a includes supplying a metal-containing gas, which adsorbs selectively onto the conductive film 12 rather than onto the insulating film 11, to the substrate surface 1a, thereby forming the metal film 18B so as to extend from the second region A2 into the first region A1 (Step S102a3).

The metal film 18B preferably contains one or more elements selected from Ru, W, and Mo, and more preferably is a Ru film. The Ru film is formed by alternately supplying Ru(EtCp)₂ gas and O₂ gas to the substrate surface 1a. The surface of the insulating film 11 has OH groups, and the OH groups inhibit adsorption of the Ru(EtCp)₂ gas. The Ru(EtCp)₂ gas does not adsorb onto a surface with OH groups, but adsorbs onto a surface without OH groups. Thus, the Ru film is formed selectively in the second region A2 rather than in the first region A1. However, the selectivity is not absolute, and the Ru film is formed so as to extend from the second region A2 into the first region A1. The deposition conditions for the Ru film may be those described in Japanese Patent Application Laid-Open Publication No. 2020-147829.

The Ru(EtCp)₂ gas does not substantially adsorb onto the first region A1. However, when defects are present in the first region A1, the Ru(EtCp)₂ gas is adsorbed onto such defects. Examples of the defects include metal remaining after polishing such as chemical mechanical planarization (CMP), or damage. Since the Ru(EtCp)₂ gas is adsorbed onto defects in the first region A1, metal particles 19 are formed in the first region A1 in a discrete manner. The metal particles 19 contain Ru.

Accordingly, as illustrated in FIG. 8, the second example of Step S102a includes removing the metal particles 19 formed in the first region A1 in Step S102a3 with an etching gas (Step S102a4). The etching gas may be, for example, ClF₃ gas or O₃ gas. Since the metal particles 19 are smaller than the metal film 18B, it is possible to remove the metal particles 19 while leaving the metal film 18B. Etching conditions for the metal particles 19 may be the same as those described in Japanese Patent Application Laid-Open Publication No. 2020-147829.

When the sacrificial film 18 is the metal film 18B, Step S102c can modify the metal film 18B into a volatile substance to remove the metal film 18B by supplying ClF₃ gas or O₃ gas to the substrate surface 1a, as in Step S102a4. The ClF₃ gas and the O₃ gas do not remove the catalyst layer 17. Accordingly, the catalyst layer 17 remains in the specific region A3. If the catalyst layer 17 does not completely cover the metal film 18B, the ClF₃ gas or the O₃ gas can remove the metal film 18B.

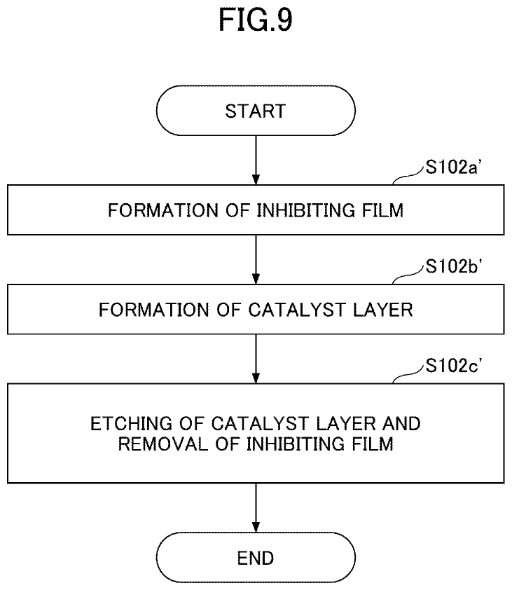

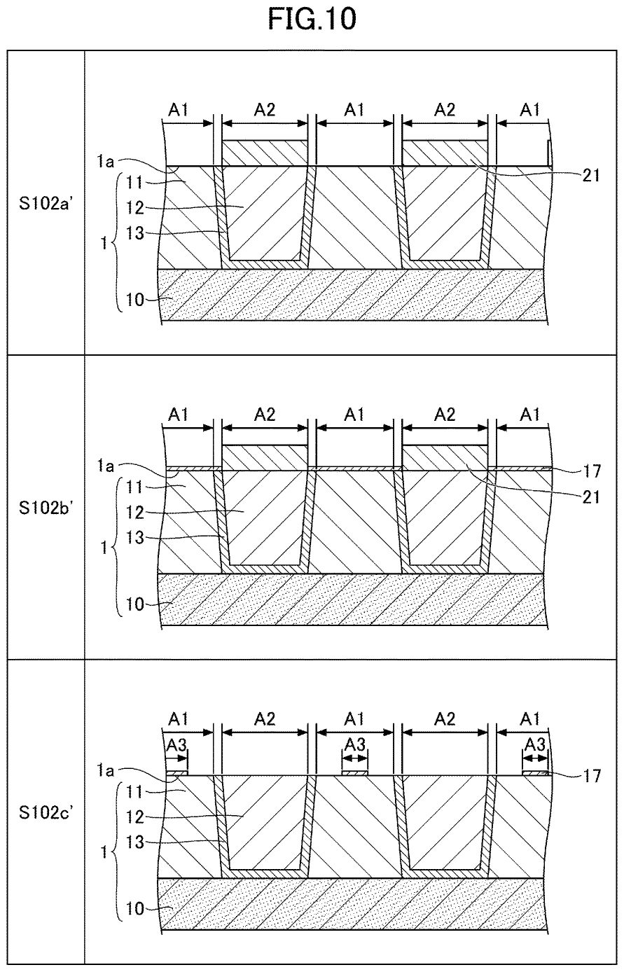

Next, a second example of Step S102 illustrated in FIG. 1 will be described with reference to FIGS. 9 and 10. Step S102 includes, for example, Steps S102a′ to S102c′ illustrated in FIGS. 9 and 10. However, Step S102 does not necessarily include all of Steps S102a′ to S102c′ illustrated in FIGS. 9 and 10. In addition, Step S102 may include a step other than Steps S102a to S102c illustrated in FIGS. 9 and 10.

As illustrated in FIG. 10, Step S102a′ includes forming an inhibiting film 21 in the second region A2 rather than in the first region A1. The inhibiting film 21 inhibits formation of the catalyst layer 17. The inhibiting film 21 is, for example, a self-assembled monolayer. The self-assembled monolayer is formed by supplying an organic compound, such as a thiol compound, in a gaseous state to the substrate surface 1a. When the organic compound is supplied in a gaseous state, organic compounds that are not adsorbed onto the substrate 1 do not remain on the substrate 1 and are exhausted. Thus, the self-assembled monolayer is less likely to extend from the first region A1 into the second region A2. Note that the inhibiting film 21 is not limited to a self-assembled monolayer, and may be, for example, a graphene-containing film. Although the inhibiting film 21 is not formed on a surface where the barrier film 13 is exposed in the present embodiment, the inhibiting film 21 may be formed on that surface.

As illustrated in FIG. 10, Step S102b′ includes forming the catalyst layer 17 on the first region A1. The catalyst layer 17 is formed, for example, using a metal-catalyst-containing gas as described above. In the present embodiment, the catalyst layer 17 is formed using only a metal-catalyst-containing gas and contains only a metal catalyst. However, the metal catalyst may be oxidized with an oxidizing gas, and the catalyst layer 17 may contain oxygen (O) in addition to the metal catalyst. That is, the catalyst layer 17 may be a metal oxide layer.

As illustrated in FIG. 10, Step S102c′ includes etching, by using components of the inhibiting film 21, an end portion of the catalyst layer 17 facing the inhibiting film 21 while decomposing the inhibiting film 21. By using the components of the inhibiting film 21, the catalyst layer 17 can be etched only in the vicinity of the inhibiting film 21. The catalyst layer 17 is etched so as to move away from a boundary between the first region A1 and the second region A2. As a result, the catalyst layer 17 remains in the specific region A3 of the first region A1.

When the inhibiting film 21 contains fluorine, step S102c′ includes supplying a gas containing H₂O to the substrate surface 1a. Hydrofluoric acid is generated by a reaction between the gas containing H₂O and the inhibiting film 21. Unnecessary portions of the catalyst layer 17 can be etched by the generated hydrofluoric acid. Products generated by the etching are volatile and are removed by exhaust. The gas containing H₂O is preferably supplied to the substrate surface 1a without being formed into a plasma so as to suppress generation of oxygen plasma. Oxidation of the conductive film 12 can be suppressed.

Step S102c′ may alternately supply, to the substrate surface 1a, a gas containing H₂O and a gas in a plasma state. A gas to be formed into a plasma is, for example, hydrogen gas, a noble gas, or a mixed gas of hydrogen gas and a noble gas. The inhibiting film 21 can be decomposed by the gas in a plasma state, and generation of hydrofluoric acid can be promoted. By alternately supplying the gas containing H₂O and the gas in a plasma state, the gas containing H₂O is not formed into a plasma, and oxidation of the conductive film 12 can be suppressed.

An example of processing conditions in Step S102c′ is shown below.

### Process 1

Flow rate of H₂ gas: 10 sccm to 500 sccm
Processing time: 0.1 sec to 120 sec
Processing temperature: 100° C. to 350° C.
Processing pressure: 50 Pa to 1200 Pa

### Process 2

Flow rate of H₂ gas: 200 sccm to 3000 sccm
Flow rate of Ar gas: 0 sccm to 6000 sccm
Proportion of H₂ gas in a mixed gas of H₂ gas and Ar gas: 20 vol % to 90 vol %
Power supply frequency for plasma generation: 10 MHz to 60 MHz
Power for plasma generation: 50 W to 600 W
Processing time: 2 sec to 120 sec
Processing temperature: 100° C. to 350° C.
Processing pressure: 50 Pa to 1200 Pa

### Number of Repetitions of Processes 1 and 2

1 to 50 repetitions

According to an aspect of the present disclosure, it is possible to provide a technique of forming a target film containing silicon (Si) and oxygen (O) in a desired region.

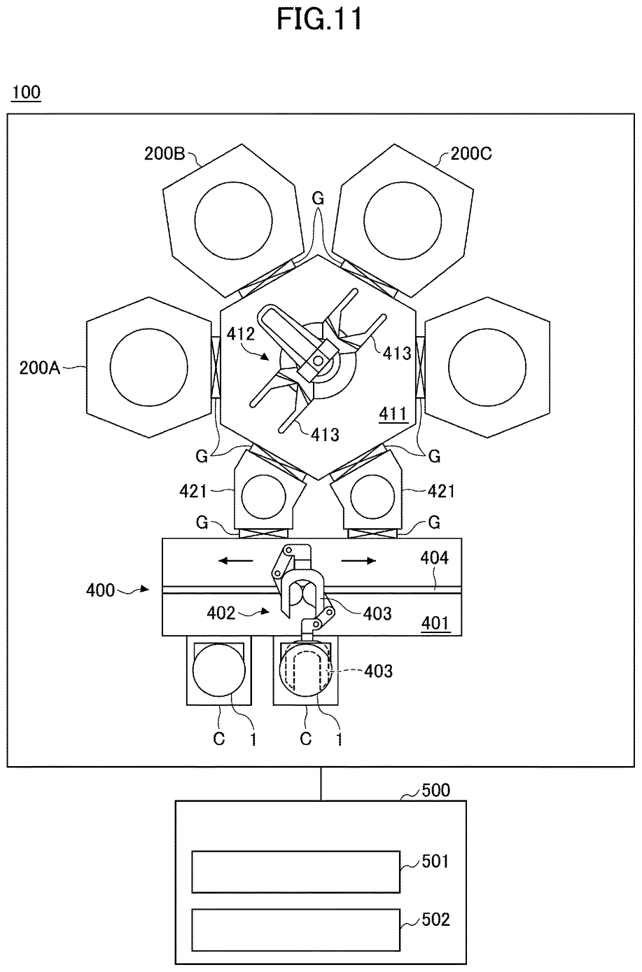

Next, a film-forming apparatus 100 for performing the above-described film-forming method will be described with reference to FIG. 11. As illustrated in FIG. 11, the film-forming apparatus 100 includes a first processing unit 200A, a second processing unit 200B, a third processing unit 200C, a transfer unit 400, and a control unit 500. The first processing unit 200A performs Step S102 in FIG. 1. The second processing unit 200B performs Step S103 in FIG. 1. The third processing unit 200C performs Step S104 in FIG. 1. The first processing unit 200A, the second processing unit 200B, and the third processing unit 200C may have the same structure or different structures. All of Steps S102 to S104 in FIG. 1 may be performed only by the first processing unit 200A. The transfer unit 400 transfers the substrate 1 to and from the first processing unit 200A, the second processing unit 200B, and the third processing unit 200C. The control unit 500 controls the first processing unit 200A, the second processing unit 200B, the third processing unit 200C, and the transfer unit 400.

The transfer unit 400 includes a first transfer chamber 401 and a first transfer mechanism 402. An internal atmosphere of the first transfer chamber 401 is an atmospheric atmosphere. The first transfer mechanism 402 is provided inside the first transfer chamber 401. The first transfer mechanism 402 includes an arm 403 that holds the substrate 1 and travels along a rail 404. The rail 404 extends in an arrangement direction of carriers C.

The transfer unit 400 further includes a second transfer chamber 411 and a second transfer mechanism 412. An internal atmosphere of the second transfer chamber 411 is a vacuum atmosphere. The second transfer mechanism 412 is provided inside the second transfer chamber 411. The second transfer mechanism 412 includes an arm 413 that holds the substrate 1, and the arm 413 is configured to be move in a vertical direction and a horizontal direction and to rotate about a vertical axis. The first processing unit 200A, the second processing unit 200B, and the third processing unit 200C are connected to the second transfer chamber 411 via corresponding gate valves G.

The transfer unit 400 further includes a load lock chamber 421 between the first transfer chamber 401 and the second transfer chamber 411. An internal atmosphere of the load lock chamber 421 is switched between a vacuum atmosphere and an atmospheric atmosphere by a pressure adjustment mechanism (not illustrated). This allows the interior of the second transfer chamber 411 to be maintained in a vacuum atmosphere at all times. Further, inflow of gas from the first transfer chamber 401 into the second transfer chamber 411 can be suppressed. Gate valves G are provided between the first transfer chamber 401 and the load lock chamber 421 and between the second transfer chamber 411 and the load lock chamber 421.

The control unit 500 is, for example, a computer, and includes a processor 501 (e.g., central processing unit (CPU)) and a storage unit 502 (e.g., a memory). The storage unit 502 stores programs for controlling various processes executed in the film-forming apparatus 100. The control unit 500 controls operation of the film-forming apparatus 100 by causing the processor 501 to execute the programs stored in the storage unit 502. The control unit 500 controls the first processing unit 200A, the second processing unit 200B, the third processing unit 200C, and the transfer unit 400 to perform the above-described film-forming method.

The control unit 500 includes an electronic circuit such as a CPU, a field programmable gate array (FPGA), or an application specific integrated circuit (ASIC), and executes various control operations described herein by executing instruction codes stored in a memory or by designing a circuit for a specific application.

Next, operation of the film-forming apparatus 100 will be described. First, the first transfer mechanism 402 removes the substrate 1 from the carrier C, transfers the substrate 1 to the load lock chamber 421, and exits the load lock chamber 421. Next, the internal atmosphere of the load lock chamber 421 is switched from an atmospheric atmosphere to a vacuum atmosphere. Thereafter, the second transfer mechanism 412 removes the substrate 1 from the load lock chamber 421 and transfers the substrate 1 to the first processing unit 200A.

Next, the first processing unit 200A performs Step S102. Thereafter, the second transfer mechanism 412 removes the substrate 1 from the first processing unit 200A and transfers the substrate 1 to the second processing unit 200B. During this time, an ambient atmosphere around the substrate 1 can be maintained in a vacuum atmosphere, and contamination of the substrate 1 can be suppressed.

Next, the second processing unit 200B performs Step S103. Thereafter, the second transfer mechanism 412 removes the substrate 1 from the second processing unit 200B and transfers the substrate 1 to the third processing unit 200C. During this time, an ambient atmosphere around the substrate 1 can be maintained in a vacuum atmosphere, and contamination of the substrate 1 can be suppressed.

Next, the third processing unit 200C performs Step S104. Thereafter, the second transfer mechanism 412 removes the substrate 1 from the third processing unit 200C, transfers the substrate 1 to the load lock chamber 421, and exits the load lock chamber 421. Subsequently, the internal atmosphere of the load lock chamber 421 is switched from a vacuum atmosphere to an atmospheric atmosphere. Thereafter, the first transfer mechanism 402 removes the substrate 1 from the load lock chamber 421 and accommodates the substrate 1 in the carrier C. Thus, processing of the substrate 1 is completed.

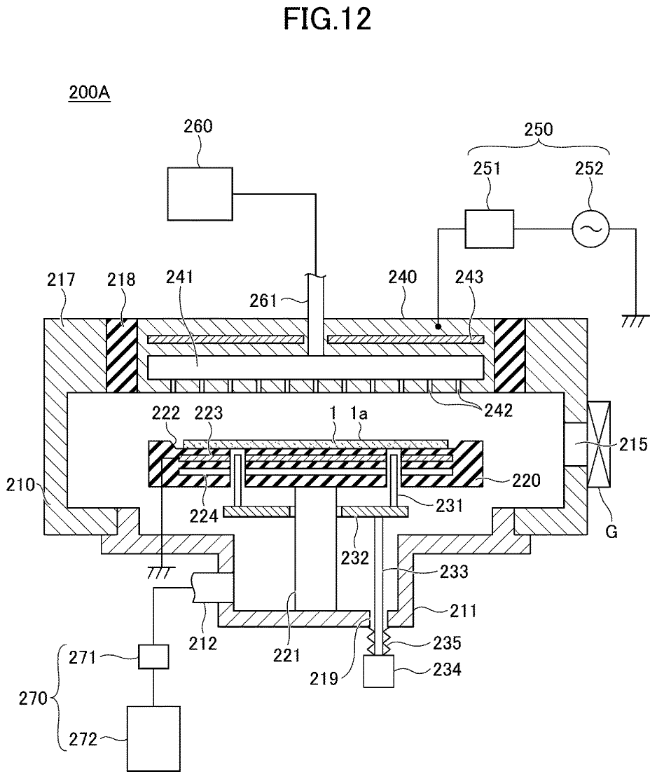

Next, the first processing unit 200A will be described with reference to FIG. 12. Note that the second processing unit 200B and the third processing unit 200C have the same configuration as the first processing unit 200A, and thus illustration and description thereof are omitted.

The first processing unit 200A includes a substantially cylindrical airtight processing chamber 210. An exhaust chamber 211 is provided at a central portion of a bottom wall of the processing chamber 210. The exhaust chamber 211 has, for example, a substantially cylindrical shape protruding downward. An exhaust pipe 212 is connected to the exhaust chamber 211, for example, on a side surface of the exhaust chamber 211.

An exhaust source (e.g., a vacuum pump) 272 is connected to the exhaust pipe 212 via a pressure controller 271. The pressure controller 271 includes, for example, a pressure regulating valve such as a butterfly valve. The exhaust pipe 212 is configured such that the interior of the processing chamber 210 can be depressurized by the exhaust source 272. The pressure controller 271 and the exhaust source 272 constitute a gas discharge mechanism 270 for discharging gas from the processing chamber 210.

A transfer port 215 is provided in a sidewall of the processing chamber 210. The transfer port 215 is opened and closed by a gate valve G. The substrate 1 is loaded and unloaded between the inside of the processing chamber 210 and the second transfer chamber 411 (see FIG. 11) through the transfer port 215.

A stage 220, which is a holder configured to hold the substrate 1, is provided inside the processing chamber 210. The stage 220 horizontally holds the substrate 1 with the substrate surface 1a facing upward. The stage 220 is formed in a substantially circular shape in plan view and is supported by a support member 221. A substantially circular recess 222 for placing the substrate 1 having, for example, a diameter of 300 mm is formed in the surface of the stage 220. The recess 222 has an inner diameter slightly greater than the diameter of the substrate 1. The depth of the recess 222 is configured to be substantially equal to, for example, the thickness of the substrate 1. The stage 220 is formed of, for example, a ceramic material such as aluminum nitride (AlN). Alternatively, the stage 220 may be formed of a metal material such as nickel (Ni). Instead of the recess 222, a guide ring for guiding the substrate 1 may be provided at a peripheral portion of the surface of the stage 220.

For example, a grounded lower electrode 223 is embedded in the stage 220. A heating mechanism 224 is embedded below the lower electrode 223. The heating mechanism 224 heats the substrate 1 placed on the stage 220 to a set temperature by being supplied with power from a power supply (not illustrated) based on a control signal from the control unit 500 (see FIG. 11). When the entire stage 220 is formed of metal, the entire stage 220 functions as the lower electrode, and thus the lower electrode 223 need not be embedded in the stage 220. The stage 220 is provided with a plurality of lift pins 231 (e.g., three lift pins 231) for holding and vertically moving the substrate 1 placed on the stage 220. The lift pins 231 may be made of, for example, a ceramic such as alumina (Al₂O₃) or quartz. Lower ends of the lift pins 231 are attached to a support plate 232. The support plate 232 is connected via a lift shaft 233 to a lifting mechanism 234 provided outside the processing chamber 210.

The lifting mechanism 234 is installed, for example, below the exhaust chamber 211. A bellows 235 is provided between an opening 219, which is formed in a lower surface of the exhaust chamber 211 for the lift shaft 233, and the lifting mechanism 234. The support plate 232 may have a shape that allows the support plate 232 to move vertically without interfering with the support member 221 of the stage 220. The lift pins 231 are configured to be moved vertically, by the lifting mechanism 234, between a position above the surface of the stage 220 and a position below the surface of the stage 220.

A gas supply 240 is provided on a top wall 217 of the processing chamber 210 via an insulating member 218. The gas supply 240 constitutes an upper electrode and faces the lower electrode 223. A high-frequency power supply 252 is connected to the gas supply 240 via a matching circuit 251. By supplying high-frequency power of 450 kHz to 100 MHz from the high-frequency power supply 252 to the upper electrode (gas supply 240), a high-frequency electric field is generated between the upper electrode (gas supply 240) and the lower electrode 223, thereby generating capacitively coupled plasma. A plasma generator 250 for generating plasma includes the matching circuit 251 and the high-frequency power supply 252. The plasma generator 250 is not limited to generating capacitively coupled plasma and may generate other plasma such as inductively coupled plasma. In a process in which plasma is not generated, the gas supply 240 need not constitute the upper electrode, and the lower electrode 223 is also unnecessary.

The gas supply 240 includes a hollow gas supply chamber 241. A plurality of holes 242 for dispersing and supplying a process gas into the processing chamber 210 are, for example, uniformly arranged on a lower surface of the gas supply chamber 241. A heating mechanism 243 is embedded in, for example, an upper portion of the gas supply 240 above the gas supply chamber 241. The heating mechanism 243 is heated to a set temperature by being supplied with power from a power supply (not illustrated) based on a control signal from the control unit 500.

A gas supply mechanism 260 is connected to the gas supply chamber 241 via a gas supply path 261. The gas supply mechanism 260 supplies, via the gas supply path 261, a gas used in at least one of Steps S102 to S104 in FIG. 1 to the gas supply chamber 241. Although not illustrated, the gas supply mechanism 260 includes, for each type of gas, an individual pipe, an opening/closing valve provided in the individual pipe, and a flow rate controller provided in the individual pipe. When the opening/closing valve opens the individual pipe, gas is supplied from a supply source to the gas supply path 261, and the supply amount is controlled by the flow rate controller. When the opening/closing valve closes the individual pipe, the supply of gas from the supply source to the gas supply path 261 is stopped.

Although the embodiments of the film-forming method and the film-forming apparatus according to the present disclosure have been described above, the present disclosure is not limited to the above embodiments. Various changes, modifications, substitutions, additions, deletions, and combinations may be made within the scope of the claims. All such variations are naturally encompassed within the technical scope of the present disclosure.

What is claimed is:

1. A film-forming method, comprising:
preparing a substrate, the substrate including, on a surface of the substrate, a first region in which an insulating film is exposed and a second region in which a conductive film is exposed;
forming a catalyst layer selectively in a specific region of the first region rather than in the second region, the catalyst layer being for promoting formation of a target film containing silicon (Si) and oxygen (O), and the specific region being spaced apart from a boundary between the first region and the second region; and
supplying, after the formation of the catalyst layer, a precursor gas to the surface of the substrate, thereby growing the target film from the specific region toward the boundary, the precursor gas containing a silanol group (SiOH group).

2. The film-forming method according to claim 1, wherein
the formation of the catalyst layer includes:
forming an inhibiting film in an entirety of the second region and the first region excluding the specific region, the inhibiting film being for inhibiting the formation of the catalyst layer;
forming, after the formation of the inhibiting film, the catalyst layer on the specific region; and
after the formation of the catalyst layer, removing the inhibiting film and leaving the catalyst layer selectively in the specific region.

3. The film-forming method according to claim 2, wherein
the inhibiting film is a self-assembled monolayer,
the formation of the inhibiting film includes applying a liquid onto the surface of the substrate and drying the liquid, the liquid being an organic compound serving as a precursor of the self-assembled monolayer, and
the removal of the inhibiting film and the leaving of the catalyst layer include supplying a gas in a plasma state to the surface of the substrate.

4. The film-forming method according to claim 1, wherein
the formation of the catalyst layer includes:
forming a sacrificial film in an entirety of the second region and the first region excluding the specific region;
forming, after the formation of the sacrificial film, the catalyst layer in the first region and the second region; and
after the formation of the catalyst layer, removing the sacrificial film and leaving the catalyst layer selectively in the specific region.

5. The film-forming method according to claim 4, wherein
the sacrificial film is a metal film,
the formation of the sacrificial film includes supplying, to the surface of the substrate, a metal-containing gas that adsorbs selectively onto the conductive film rather than onto the insulating film, and
the removal of the sacrificial film and the leaving of the catalyst layer includes supplying ClF₃ gas or O₃ gas to the surface of the substrate.

6. The film-forming method according to claim 5, wherein
the metal film contains one or more elements selected from Ru, W, and Mo.

7. The film-forming method according to claim 1, wherein
the formation of the catalyst layer includes:
forming an inhibiting film selectively in the second region rather than in the first region, the inhibiting film being for inhibiting the formation of the catalyst layer;
forming, after the formation of the inhibiting film, the catalyst layer in the first region; and
etching, after the formation of the catalyst layer, by using a component of the inhibiting film, an end portion of the catalyst layer, the end portion facing the inhibiting film.

8. The film-forming method according to claim 1, further comprising:
after the formation of the catalyst layer and before the supply of the precursor gas, supplying a gas in a plasma state to the surface of the substrate on which the catalyst layer is formed, thereby activating the catalyst layer.

9. A film-forming apparatus, comprising:
a processing chamber;
a holder configured to hold the substrate inside the processing chamber;
a gas supply mechanism configured to supply a gas to an interior of the processing chamber;
a gas discharge mechanism configured to discharge gas from the interior of the processing chamber;
a transfer mechanism configured to load and unload the substrate onto and from the processing chamber; and
control circuitry configured to control the gas supply mechanism, the gas discharge mechanism, and the transfer mechanism to perform the film-forming method of claim 1.
